(19) United States
(12) Patent Application Publication
(10) Pub. No.: US 2024/0130211 A1
(43) Pub. Date: Apr. 18, 2024

(54) DEPOSITION MASK, AND METHOD FOR PRODUCING ORGANIC LIGHT-EMITTING ELEMENT

(71) Applicant: CANON KABUSHIKI KAISHA, Tokyo (JP)

(72) Inventors: MASUMI ITABASHI, Kanagawa (JP); HIROYUKI MOCHIZUKI, Kanagawa (JP); TATSURO UCHIDA, Tokyo (JP)

(21) Appl. No.: 18/479,966

(22) Filed: Oct. 3, 2023

(30) Foreign Application Priority Data
Oct. 18, 2022 (JP) 2022-166808

(51) Int. Cl. H10K 71/16; H10K 50/88; H10K 77/10

(52) U.S. Cl. CPC H10K 71/166; H10K 50/88; H10K 77/10; H10K 2102/302

(57) ABSTRACT

There is provided a deposition mask in which a plurality of pixel openings are disposed in a surface, of a deposition mask, which is to face a substrate on which a deposition pattern is deposited. Protrusions including a material different from a material included in the deposition mask are formed in a region which is located from a pixel opening that is disposed at an outermost peripheral portion in the surface, from among the plurality of pixel openings, up to an edge of the deposition mask. In the deposition mask, a crosspiece which is located between two pixel openings adjacent to each other, from among the plurality of pixel openings include the material.

### BACKGROUND OF THE INVENTION

### Field of the Invention

The art in the present disclosure relates to a deposition mask for deposition of a pixel opening pattern on a substrate, and to a method for producing an organic light-emitting element in which that deposition mask is utilized.

### Description of the Related Art

Organic light-emitting elements are attracting attention as light-emitting elements capable of emitting high-luminance light by low-voltage driving. Organic light-emitting elements are ordinarily formed as a plurality of multilayer structures in the form of an anode, a hole-transporting layer, a light-emitting layer, an electron-transporting layer and a cathode, on a substrate. Examples of methods for forming such a multilayer structure include vacuum deposition onto substrates, relying on evaporation or sublimation, and film formation methods that rely for instance on inkjet or spin coating of an organic material having been dissolved in a solvent.

In the foregoing methods it is commonplace to form a multilayer structure using low-molecular materials, by vacuum deposition in which a mask is used that has a pattern disposed thereon. In order to form a film having a desired pattern on a substrate in a vacuum deposition method, a deposition mask having a desired pixel opening pattern is placed between the substrate and a heating portion of a deposition material, to form the film.

Recent years have witnessed a demand for organic light-emitting elements of higher definition. Achieving high-definition organic light-emitting elements requires bringing a substrate and a deposition mask very close to each other, so as to reduce deposition blur and deposition vignetting at the time of deposition. Deposition blur signifies that the deposition material is deposited over a wide range that exceeds the desired deposition range. The distance between the substrate and the deposition mask is important in this respect. Even if the substrate and the deposition mask can be set according to the envisaged positional relationship at the time of deposition, crosspieces that demarcate pixel openings experience deflection, for instance at the central portion of the deposition mask, on account of the own weight of the mask, giving rise to deposition blur. Deposition vignetting occurs when the deposition range is cut off due to the influence of the thickness of the crosspieces or of a frame of the deposition mask. The crosspieces and frame need to be made thinner in order to reduce the impact of deposition blur and deposition vignetting.

When the substrate and the deposition mask are brought close to each other during deposition, however, the substrate and the deposition mask adhere to each other on account of interactions such as van der Waals forces. As a result, the crosspieces that define the pixel openings of the deposition mask become damaged, for instance distorted or cut, when the substrate and the deposition mask are stripped off each other after deposition; this makes it difficult to perform a deposition process on a plurality of substrates. The above also results in substrate damage and in sources of foreign matter, which translates into lower yield. This has remained a problem to be solved, in that to achieve organic light-emitting elements of higher definition, it is however indispensable to bring the substrate and the deposition mask close to each other at the time of deposition.

Japanese Patent Application Publication No. 2003-59671 proposes providing ribs and spacers around a pixel region of a substrate, for the purpose of preventing damage derived from the proximity between the substrate and a deposition mask. Japanese Patent Application Publication No. 2003-59671 allows bringing the substrate and the deposition mask closer to each other by a desired distance, but without the substrate and the deposition mask coming near at a distance equal to or smaller than the height of the spacers. In Japanese Patent Application Publication No. 2003-59671, however, the influence of the above-described deposition blur may in some instances fail to be suppressed, since the deposition mask still deflects on account of its own weight.

In Japanese Patent Application Publication No. 2006-233286, a magnetic film is provided on a deposition mask, as a result of which the deposition mask can be attracted by means of magnets provided on the surface, of the deposition mask, on the reverse side from that of the substrate-facing surface; in turn, this allows curtailing the impact of for instance deposition blur. However, with a view to suppressing the phenomenon of deflection of the deposition mask on account of its own weight, the magnetic film is disposed at the central portion of the deposition mask, for the purpose of lifting up the portion of greater deflection. In Japanese Patent Application Publication No. 2006-233286, therefore, adhesion between the substrate and the deposition mask may fail to be mitigated.

Japanese Patent Application Publication No. 2015-148002 indicates that the substrate-facing surface of a deposition mask is made of a resin, such that part of that surface is roughened, to thereby mitigate adhesion between the substrate and the deposition mask. Given however that the surface of the deposition mask is brought to a roughened state, adhesion between the deposition mask and the substrate at non-roughened portions may fail to be mitigated in some instances.

### SUMMARY OF THE INVENTION

It is an object of the art of the present disclosure, arrived at in the light of the above considerations, to lower damage and deflection in a deposition mask at the time of stripping of the deposition mask and a substrate from each other after deposition of a pixel opening pattern on the substrate.

According to some embodiments, there is provided a deposition mask wherein a plurality of pixel openings are disposed in a surface, of a deposition mask, which is to face a substrate on which a deposition pattern is deposited, wherein protrusions including a material different from a material included in the deposition mask are formed in a region which is located from a pixel opening that is disposed at an outermost peripheral portion in the surface, from among the plurality of pixel openings, up to an edge of the deposition mask, and wherein in the deposition mask, a crosspiece which is located between two pixel openings adjacent to each other, from among the plurality of pixel openings include the material.

According to some embodiments, a method for producing an organic light-emitting element includes forming an organic compound layer using the above deposition mask. According to some embodiments, a display device includes an organic light-emitting element having an organic compound layer formed using the above deposition mask. According to some embodiments, an imaging device includes an organic light-emitting element having an organic compound layer formed using the above deposition mask. According to some embodiments, an electronic device includes an organic light-emitting element having an organic compound layer formed using the above deposition mask. According to some embodiments, a lighting device includes an organic light-emitting element having an organic compound layer formed using the above deposition mask. According to some embodiments, a moving body includes an organic light-emitting element having an organic compound layer formed using the above deposition mask.

Further features of the present invention will become apparent from the following description of exemplary embodiments with reference to the attached drawings.

### BRIEF DESCRIPTION OF THE DRAWINGS

FIG. 1 is a schematic diagram of a deposition mask according to an embodiment;

FIG. 2A to FIG. 2H are diagrams illustrating a method for producing a deposition mask according to the present embodiment;

FIG. 3A and FIG. 3B are diagrams illustrating a top view of a deposition mask according to the present embodiment;

FIG. 4A to FIG. 4D are plan-view diagrams and cross-sectional diagrams illustrating examples of a deposition mask having protrusions, of the present embodiment;

FIG. 5A to FIG. 5D are plan-view diagrams and cross-sectional diagrams illustrating other examples of a deposition mask having protrusions, of the present embodiment;

FIG. 6A and FIG. 6B are plan-view diagrams and cross-sectional diagrams illustrating yet other examples of a deposition mask having protrusions, of the present embodiment;

FIG. 7A to FIG. 7D are plan-view diagrams and cross-sectional diagrams illustrating yet other examples of a deposition mask having protrusions, of the present embodiment;

FIG. 8A and FIG. 8B are plan-view diagrams and cross-sectional diagrams illustrating yet other examples of a deposition mask having protrusions, of the present embodiment;

FIG. 9A and FIG. 9B are diagrams illustrating examples of a display device having an organic light-emitting element according to the present embodiment;

FIG. 10 is a diagram illustrating an example of a display device having an organic light-emitting element according to the present embodiment;

FIG. 11A and FIG. 11B are diagrams illustrating examples of a display device and of an electronic device having an organic light-emitting element according to the present embodiment;

FIG. 12A and FIG. 12B are schematic diagrams illustrating examples of a display device having an organic light-emitting element according to the present embodiment;

FIG. 13A and FIG. 13B are diagrams illustrated in an example of a lighting device and a moving body having an organic light-emitting element according to the present embodiment; and

FIG. 14A and FIG. 14B are schematic diagrams illustrating examples of spectacles having an organic light-emitting element according to the present embodiment.

### DESCRIPTION OF THE EMBODIMENTS

Embodiments of the present disclosure will be explained below with reference to accompanying drawings. The present disclosure is not limited to the following embodiments, and can thus be altered as appropriate, without departing from the scope of the present disclosure. In the drawings below, features having identical functions are denoted identical reference symbols, and an explanation thereof may be omitted or simplified.

### First Embodiment

A deposition mask used in a first embodiment will be explained next. The deposition mask according to the present embodiment is used for the purpose of forming a desired deposition pattern on a substrate, in accordance with a vacuum deposition method. Examples of members that are used herein include, although not particularly limited to, stainless steel, iron, copper, aluminum, silver, titanium, molybdenum, tungsten, invar, silicon and resins. The above members may form a deposition mask each singly, or in combinations of a plurality of members.

For instance wet etching can be resorted to as an example of a method for producing a metal-made deposition mask. Examples of methods for producing a silicon-made deposition mask include a method that involves processing an SOI (Silicon on Insulator) wafer. The method for producing the deposition mask of the present embodiment is not limited to these production methods.

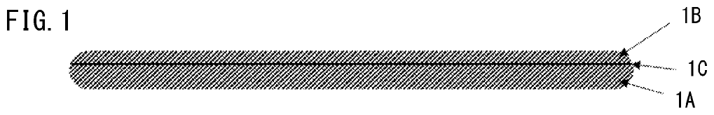

FIG. 1 schematically illustrates an example of a silicon-made deposition mask according to the present embodiment. From among two Si layers of a SOI wafer, as illustrated in FIG. 1, the thicker layer is referred to as Si support layer 1A and the thinner layer is referred to as Si functional layer 1B, the front surface side of the SOI wafer being herein the Si functional layer 1B. A silicon oxide layer 1C is sandwiched between the two Si layers 1A and 1B.

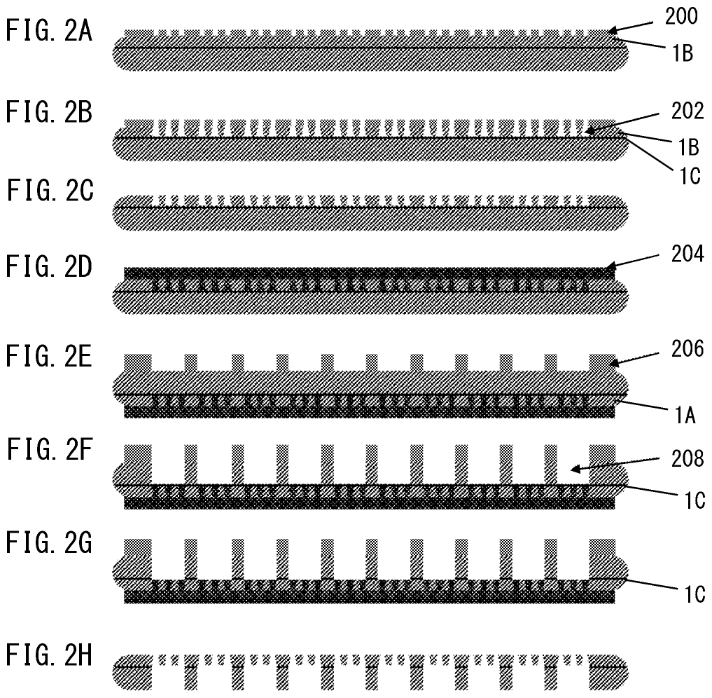

A method for producing a deposition mask will be explained more specifically with reference to FIG. 2A to FIG. 2H.
(1) A first resist pattern 200 having holes for forming a deposition layer of a desired size by letting through a deposition material, is formed, by photolithography, on the Si functional layer 1B on the surface of the SOI wafer, as illustrated in FIG. 2A.
(2) As illustrated in FIG. 2B, the Si functional layer 1B on the surface of the SOI wafer is next dry-etched, to form as a result first Si holes 202 having had the first resist pattern 200 transferred thereto. Herein the silicon oxide layer 1C formed under the Si functional layer 1B functions as an etching stop layer.
(3) The first resist pattern 200 is removed next by oxygen plasma ashing, as illustrated in FIG. 2C.
(4) In order to protect the first Si holes 202 formed in the SOI wafer surface, a resist is applied next onto the SOI wafer surface, to form a protective layer 204, as illustrated in FIG. 2D.
(5) As illustrated in FIG. 2E, a second resist pattern 206 having the aggregate size of the first Si holes 202 is formed next, by photolithography, on the Si support layer 1A on the back surface of the SOI wafer. The term aggregate size of the first Si holes denotes herein for instance a size corresponding to the size of one display device chip size.
(6) As illustrated in FIG. 2F, the Si support layer on the back surface of the SOI wafer is next dry-etched, to form second Si holes 208 having had the second resist pattern transferred thereto. The silicon oxide layer 1C functions as an etching stop layer in this case as well.
(7) As illustrated in FIG. 2G, wet etching is performed next using buffered hydrofluoric acid, to etch the silicon oxide layer 1C. At this time the size of the silicon oxide layer 1C that is etched is the size of the second Si holes formed on the back surface of the SOI wafer.
(8) As illustrated in FIG. 2H, the deposition mask is then completed through removal of the second resist pattern 206, as a result of an organic wet treatment.

Protruded portions of the deposition mask according to the present embodiment will be explained next. The protrusions of the deposition mask according to the present embodiment are used for the purpose of reducing the contact surface area with a substrate, in a set of a substrate and the deposition mask. The protrusions are formed on the substrate-facing surface of the deposition mask, and hence it is possible to achieve the minimum necessary contact surface such that the substrate and the deposition mask do not adhere to each other.

The material used in the protrusions is not particularly limited so long as it differs from the material of the deposition mask member that adheres to the protrusions. In a case where a magnetic material is used in the protrusions, the material is preferably selected from among cobalt Co, iron Fe, nickel Ni, and substances containing the foregoing. Specifically, the protrusions can be formed, by electroless plating or the like, using for instance Ni—Fe—P or Co—Ni—P. Materials typified by resin materials and release agents can be used by contrast in a case where a non-magnetic material is used in the protrusions. Examples of the resin material include, although not particularly limited to, polyimides and polyamides. In a case where the protrusions are formed using a resin material, the protrusions are obtained through formation thereof on the mask, using a dispenser, followed by thermal curing in an oven. Examples of the release agent include, although not limited to, fluorine-based, silicon-based and wax-based release agents. Particularly preferably, the release agent is selected from among fluorine-based materials. In a case where a plurality of protrusions are formed, a single type of material from among the above materials, or a plurality of types of materials, may be selected as the material utilized in respective protrusions.

For instance a region having present therein protrusions made up of a magnetic material and a region having present therein protrusions made up of a non-magnetic material may be co-present on the deposition mask. Also, one protruded portion may be formed by applying a release agent having release characteristics onto a protruded portion made up of the above magnetic material.

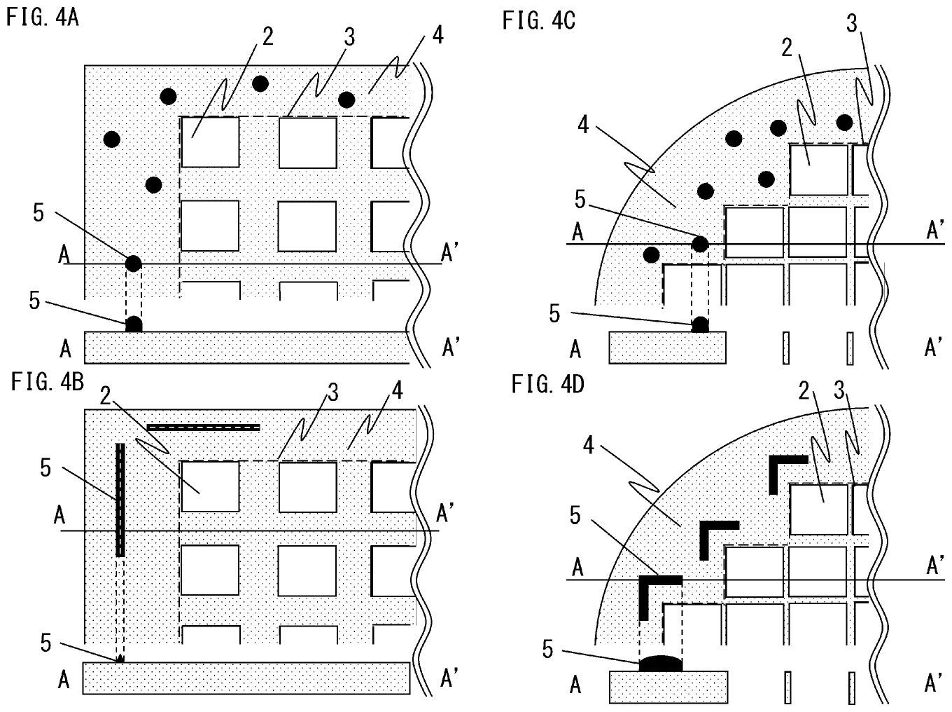

Examples of protrusions of the deposition mask according to the present embodiment will be explained next. The shape of the protrusions that are formed on the substrate-facing surface of the deposition mask is not limited to ellipses and triangles such as those illustrated in FIG. 4A to FIG. 4D to FIG. 8A and FIG. 8B, and may be for instance semicircles, polygons and bell shapes. The shape of the protrusions is not limited to the foregoing. The shape of the contact surface of the substrate and the deposition mask may be a point contact shape or a line contact shape, the shape of the contact surface of the substrate and the deposition mask may be a shape that elicits surface contact, as long as the contact surface it is not smaller than the width of crosspieces that delimit respective pixel openings. The shapes of the plurality of protrusions formed on one deposition mask may be identical, or may by mutually different. The sizes of the plurality of protrusions formed on one deposition mask may be identical to each other, or may be different from each other.

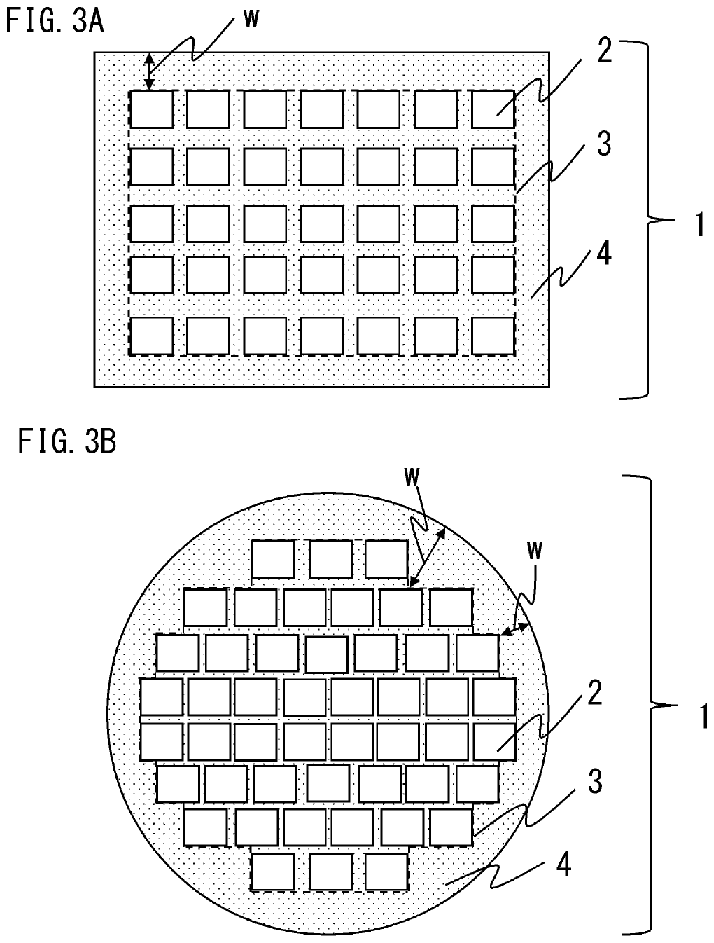

Details about the protrusions will be explained next with reference to accompanying drawings. FIG. 3A and FIG. 3B schematically illustrate top-view diagrams of deposition masks 1 of the present embodiment that adopt general deposition mask shapes. Each deposition mask 1 has a plurality of pixel openings 2, such that protrusions are formed in a region 4 between a boundary 3 that defines the outermost peripheral portion of the pixel openings 2, and the edge of the deposition mask 1. FIG. 4A to FIG. 4D to FIG. 8A and FIG. 8B illustrate concrete examples of the protrusions. The protrusions are formed of a material different from that of the deposition mask 1 on which the protrusions are disposed. This allows imparting functionality to the protrusions. As illustrated in FIG. 3A and FIG. 3B, a width W of the region 4 need not be constant in one given deposition mask 1.

As a concrete example of the protrusions, in a case where the deposition mask 1 is made up of a non-magnetic material and the protrusions are formed of a magnetic material, then deflection of the deposition mask 1 on account of its own weight can be eased through the use of the of magnets. In a case where the material of the deposition mask 1 is a magnetic material, the protrusions may be formed out of a release agent. As a result, it becomes possible to combine lessening of the deflection of the deposition mask 1 when the deposition mask 1 is pulled up using magnets, and easier stripping of the deposition mask 1 when the deposition mask 1 is peeled off the substrate.

At the time of peeling of the deposition mask 1 off the substrate, forces are exerted in a direction of lifting the substrate up, a direction of vertically lowering the deposition mask 1, or in both these directions. At that time, the entirety or a partial area of the region 4 of the deposition mask 1 begins to peel off the substrate. Crosspieces that delimit the pixel openings then peel sequentially off the substrate, from the pixel openings 2 disposed at the outermost peripheral portion of the deposition mask 1 close to the region 4 towards the pixel openings 2 disposed at a central portion of the deposition mask 1. Herein the region 4 is a portion where the contact surface area between the substrate and the deposition mask is greatest. Distortion and damage to the deposition mask 1 can be prevented by facilitating stripping at the region 4.

FIG. 4A to FIG. 4D to FIG. 8A and FIG. 8B illustrate examples of the layout of the protrusions 5 of the deposition mask 1 according to the present embodiment. The arrangement of the protrusions 5 that are formed on the deposition mask 1 is however not limited to the arrangements illustrated in these figures. FIG. 4A and FIG. 4B illustrate examples of protrusions 5 formed on the deposition mask 1 illustrated in FIG. 3A, and FIG. 4C and FIG. 4D illustrate examples of protrusions 5 formed on the deposition mask 1 illustrated in FIG. 3B. FIG. 4A to FIG. 4D illustrate part of a respective deposition mask 1, viewed from above, and a cross section along a respective line A-A′. As illustrated in FIG. 4A to FIG. 4D, the shape of the protrusions 5 formed on the deposition mask 1 may be a projecting shape, as in FIG. 4A and FIG. 4C, a rectangular rod-like shape as viewed from above, as illustrated in FIG. 4B, or a polygonal line shape as viewed from above, illustrated in FIG. 4D.

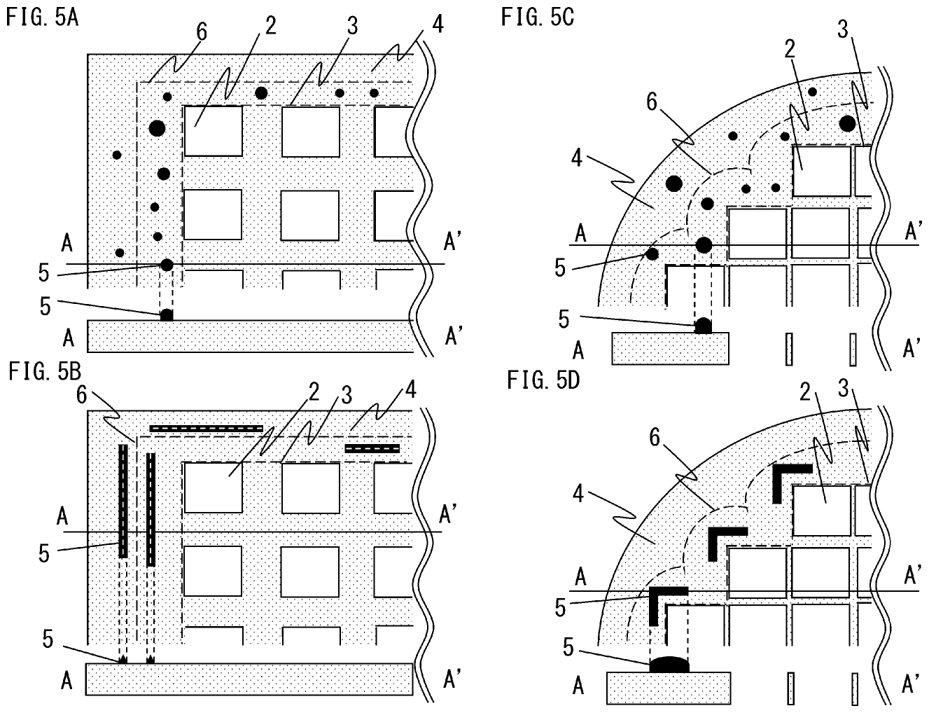

FIG. 5A and FIG. 5B illustrate examples of protrusions 5 formed on the deposition mask 1 illustrated in FIG. 3A, and FIG. 5C and FIG. 5D illustrate examples of protrusions 5 formed on the deposition mask 1 illustrated in FIG. 3B. FIG. 5A to FIG. 5D illustrate part of a respective deposition mask 1, viewed from above, and a cross section along a respective line A-A′. Concerning the positions at which the protrusions 5 are formed, preferably the protrusions 5 may be formed within the region 4, as illustrated in FIG. 5A to FIG. 5D, at least within a range (region inward of a boundary 6 in the figure) of a width W/2 from the boundary 3 towards the edge of the deposition mask 1. One of the portions of the deposition mask 1 that is acted upon by a greatest load upon peeling off the substrate is herein the crosspieces that surround the pixel openings 2 disposed at the outermost peripheral portion, and the region 4. By virtue of the fact that protrusions 5 are formed in a region inward of the boundary 6, it becomes possible to reduce the load on the deposition mask 1, at the time where the deposition mask 1 is peeled off the substrate, and to prevent deflection and damage to the deposition mask 1.

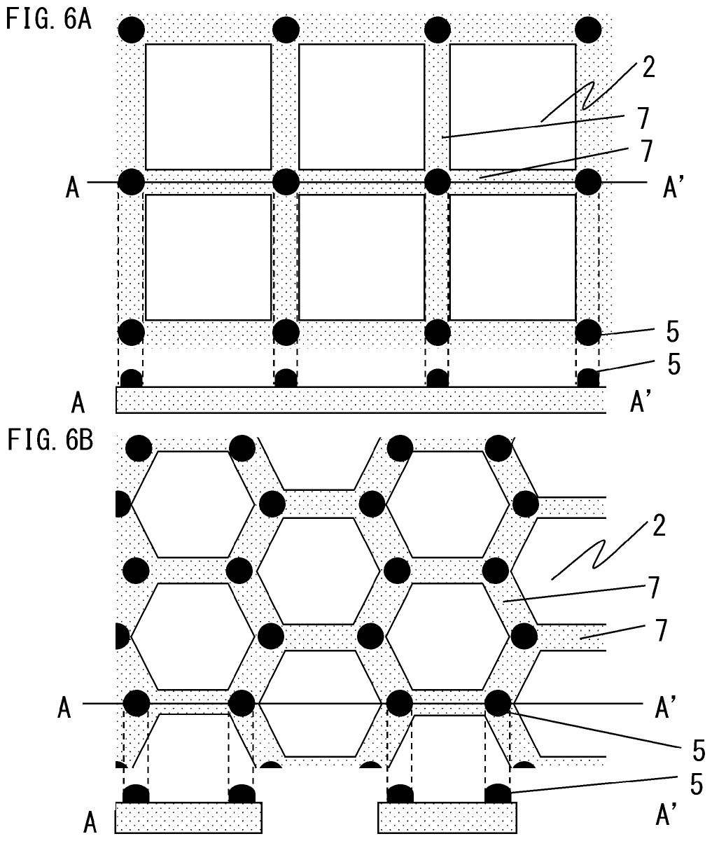

FIG. 6A illustrates an example of the protrusions 5 formed on the deposition masks 1 illustrated in FIG. 3A and FIG. 3B, and FIG. 6B illustrates an example of the protrusions 5 formed on the deposition mask 1 in a case where pixel openings 2 are disposed that have a different shape, as a variation of the deposition masks 1 illustrated in FIG. 3A and FIG. 3B. FIG. 6A and FIG. 6B illustrate part of a respective deposition mask 1, viewed from above, and a cross section along a respective line A-A′. As illustrated in FIG. 6A and FIG. 6B, protrusions 5 are formed at positions facing respective corners of the pixel openings 2, on crosspieces 7 of the deposition mask 1. At the time of stripping of the deposition mask 1 off the substrate, therefore, the deposition mask 1 can be peeled off more easily, and deflection and damage to the deposition mask 1 can be prevented, by virtue of the fact that protrusions 5 are formed at positions where a larger load is envisaged to act on the crosspieces 7.

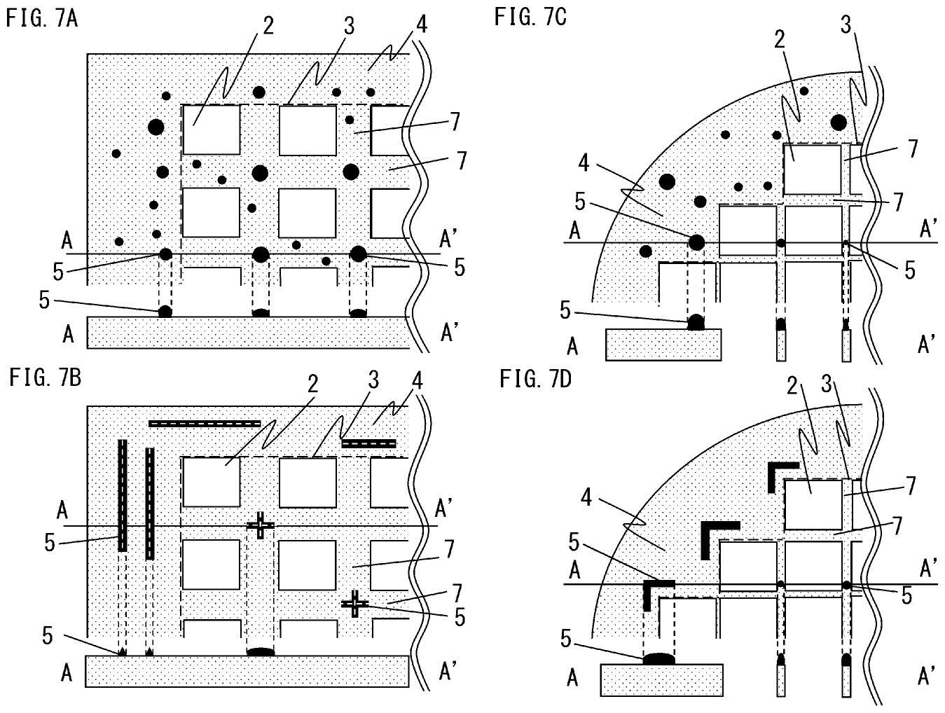

FIG. 7A and FIG. 7B illustrate examples of protrusions 5 formed on crosspieces of the deposition mask 1 illustrated in FIG. 3A, and FIG. 7C and FIG. 7D illustrate examples of protrusions 5 formed on crosspieces the deposition mask 1 illustrated in FIG. 3B. FIG. 7A to FIG. 7D illustrate part of a respective deposition mask 1, viewed from above, and a cross section along a respective line A-A′. Concerning the positions at which the protrusions 5 are formed, preferably the protrusions 5 are formed on the crosspieces 7 that delimit respective pixel openings 2 and that are disposed in the deposition mask 1, illustrated in FIG. 7A to FIG. 7D. The protrusions 5 can be formed to arbitrary sizes and shapes on the crosspieces 7, as illustrated in the figures.

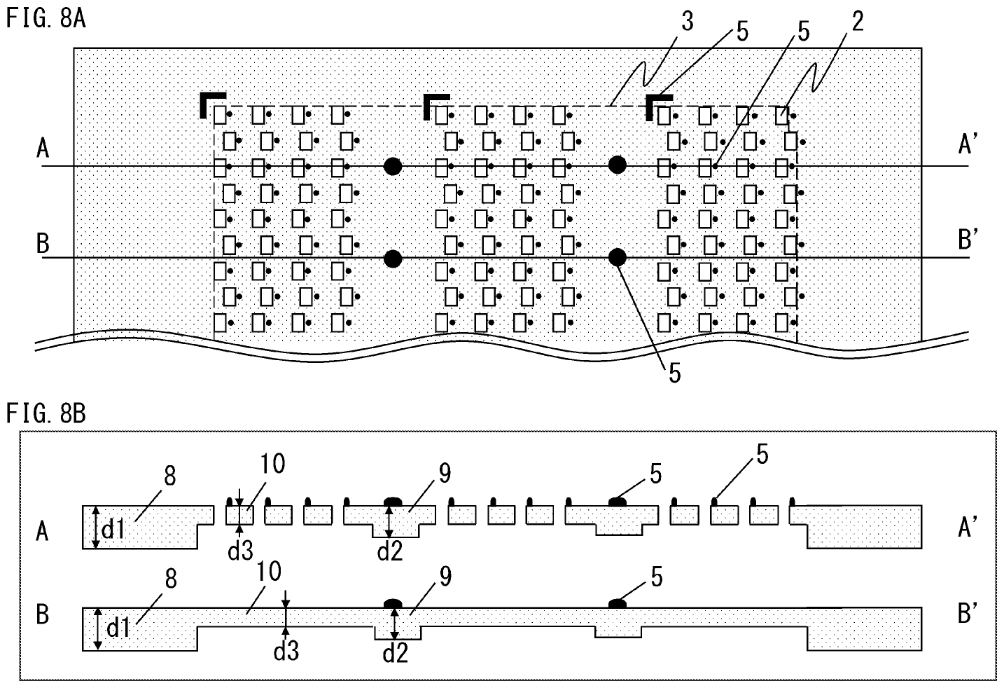

The thickness of the deposition mask 1 may be uniform or non-uniform. The thickness of deposition mask 1 may be dissimilar at different portions. An example of the thickness of the deposition mask 1 will be explained with reference to FIG. 8A and FIG. 8B. FIG. 8A is a top-view diagram illustrating part of the deposition mask 1, and FIG. 8B is a set of cross-sectional diagrams of FIG. 8A along line A-A′ and along line B-B′. As illustrated in FIG. 8A, the deposition mask 1 has a frame 8 corresponding to a portion surrounding the boundary 3 that defines the region at which the pixel openings 2 are disposed, being a region at the edge of the deposition mask 1, and crosspieces 9, 10 that demarcate the pixel openings 2. When the deposition mask 1 is viewed from above, the width of the crosspieces 9 is larger than the width of the crosspieces 10, as illustrated in FIG. 8A and FIG. 8B.

As illustrated in the figures, d1, d2 and d3 respectively denote the values of thickness of the frame 8, the crosspieces 9 and the crosspieces 10. A relationship between these thickness values obeys Expression (1).

d1≥d2≥d3 (1)

The frame 8 is a region of contact with a support member, such as a mask holder, at a time where the deposition mask 1 is supported within a deposition apparatus; herein it suffices that the frame 8 be thick enough so as to withstand the own weight of the deposition mask 1, and in terms of manufacture of the deposition mask 1, preferably the frame 8 is the thickest portion of the deposition mask 1. Vignetting at the time of deposition, derived from the structure itself of the pixel openings 2, can be suppressed by making the crosspieces 10 that define the pixel openings 2 sufficiently thin relative to the aperture width of the pixel openings 2. By contrast, the smaller the pixel openings 2 and the higher an aperture ratio over the entirety of the of the deposition mask 1, the lower is the mechanical strength of the deposition mask 1. Accordingly, the mechanical strength of the deposition mask 1 can be improved by forming the deposition mask 1 so as to partially have the crosspieces 9 that are thicker than the crosspieces 10. As the figures reveal, the crosspieces 9 are portions at which pixel openings are formed at a spacing larger than the spacing of the plurality of pixel openings that form the crosspieces 10. The crosspieces 9 are an example of a first crosspiece, and the crosspieces 10 are an example of a second crosspiece. In order to suppress drops in mechanical strength derived from a reduction in the size of the pixel openings 2 of the deposition mask 1, it is yet more preferable to provide the frame 8 and the crosspieces 9, 10 in the deposition mask 1 such that respective thickness values of the foregoing satisfy the relationship in Expression (1) above. Therefore, the deposition mask, in an example, has a frame in contact with a support member of the deposition mask, and a thickness of the frame is greater than a thickness of a first crosspiece, in a thickness direction of the deposition mask.

More preferably, the protrusions 5 are formed on the crosspieces 10. The material of the protrusions 5 provided on the crosspieces 10 that demarcate the plurality of pixel openings 2 in the deposition mask 1 of the present embodiment is not particularly limited, but preferably at least one from among the protrusions 5 provided on the crosspieces 10 may be made up of a magnetic material. FIG. 8B illustrates an instance where the deposition mask 1 is made up of a single material; however, the thickness of each portion of the deposition mask 1 may be set as described above also in a case where the deposition mask 1 is made up of a plurality of materials.

[Structure of an Organic Light-Emitting Element] An organic light-emitting element produced using the deposition mask 1 of the present embodiment will be explained next. In the present embodiment the organic light-emitting element is provided by forming an insulating layer, a first electrode, an organic compound layer and a second electrode, on a substrate. A protective layer, a color filter, a microlens and so forth may be provided on a cathode. In a case where a color filter is provided, a planarization layer may be provided between the color filter and the protective layer. The planarization layer can be for instance made up of an acrylic resin. The same is true in a case where the planarization layer is provided between the color filter and the microlens.

[Substrate] At least one material selected from quartz, glass, silicon, resins and metals can be used as the material for the substrate that makes up the organic light-emitting element. Switching elements such as transistors and wiring may be provided on the substrate, and an insulating layer may be provided on the foregoing. Any material can be used as the insulating layer so long as a contact hole can be formed between the insulating layer and the first electrode, and insulation from unconnected wiring can be ensured, so that wiring can be formed between the first electrode and the insulating layer. For instance a resin such as a polyimide, or silicon oxide or silicon nitride can be used herein.

[Electrodes] A pair of electrodes can be used as the electrodes of the organic light-emitting element. The pair of electrodes may be an anode and a cathode. In a case where an electric field is applied in the direction in which the organic light-emitting element emits light, the electrode of higher potential is the anode, and the other electrode is the cathode. Stated otherwise, the electrode that supplies holes to the light-emitting layer is the anode, and the electrode that supplies electrons is the cathode.

A material having a work function as large as possible is preferable herein as a constituent material of the anode. For instance single metals such as gold, platinum, silver, copper, nickel, palladium, cobalt, selenium, vanadium or tungsten, and mixtures containing the foregoing metals, can be used in the anode. Alternatively, alloys obtained by combining these single metals, or metal oxides such as tin oxide, zinc oxide, indium oxide, indium tin oxide (ITO) or indium zinc oxide, may be used in the anode. Conductive polymers such as polyaniline, polypyrrole and polythiophene can also be used in the anode.

Any of the foregoing electrode materials may be used singly; alternatively, two or more materials may be used concomitantly. The anode may be made up of a single layer, or may be made up of a plurality of layers.

In a case where an electrode of the organic light-emitting element is configured in the form of a reflective electrode, the electrode material can be for instance chromium, aluminum, silver, titanium, tungsten, molybdenum, or alloys or layered bodies of the foregoing. The above materials can also function as a reflective film not having a role as an electrode. In a case where an electrode of the organic light-emitting element is configured in the form of a transparent electrode, for instance an oxide transparent conductive layer of for instance indium tin oxide (ITO) or indium zinc oxide can be used, although not particularly limited thereto, as the electrode material. The electrodes may be formed by photolithography.

A material having a small work function may be a constituent material of the cathode. For instance alkali metals such as lithium, alkaline earth metals such as calcium, single metals such as aluminum, titanium, manganese, silver, lead or chromium, and mixtures of the foregoing, may be used herein. Alternatively, alloys obtained by combining these single metals can also be used. For instance magnesium-silver, aluminum-lithium, aluminum-magnesium, silver-copper or zinc-silver can be used. Metal oxides such as indium tin oxide (ITO) can also be used. These electrode materials may be used singly as one type, or two or more types can be used concomitantly. Also, the cathode may have a single-layer structure or a multilayer structure. Silver is preferably used among the foregoing, and more preferably a silver alloy, in order to reduce silver aggregation. Any alloy ratio can be adopted, so long as silver aggregation can be reduced. A ratio silver: other metal may be for instance 1:1, or 3:1.

Although not particularly limited thereto, the cathode may be a top emission element that utilizes an oxide conductive layer of ITO or the like, or may be a bottom emission element that utilizes a reflective electrode of aluminum (Al) or the like. The method for forming the cathode is not particularly limited, but more preferably for instance a DC or AC sputtering method is resorted to, since in that case film coverage is good and resistance can be readily lowered.

[Pixel Separation Layer] The pixel separation layer of the organic light-emitting element is formed out of a silicon nitride (SiN) film, a silicon oxynitride (SiON) film, or a silicon oxide (SiO) film, in turn having been formed by chemical vapor deposition (CVD). In order to increase the in-plane resistance of the organic compound layer, preferably the thickness of the organic compound layer that is formed, particularly a hole transport layer, is set to be small at the side walls of the pixel separation layer. Specifically, the side walls can be formed to be thin by increasing vignetting at the time of deposition, through an increase of the taper angle of the side walls of the pixel separation layer and/or an increase of the thickness of the pixel separation layer.

On the other hand, it is preferable to adjust the side wall taper angle of the pixel separation layer and the thickness of the pixel separation layer so that no voids are formed in the protective layer that is formed on the pixel separation layer. The occurrence of defects in the protective layer can be reduced by virtue of the fact that no voids are formed in the protective layer. Since the occurrence of defects in the protective layer is thus reduced, it becomes possible to reduce loss of reliability for instance in terms of the occurrence of dark spots or defective conduction in the second electrode.

The present embodiment allows effectively suppressing leakage of charge to adjacent pixels even when the taper angle of the side walls of the pixel separation layer is not sharp. Studies by the inventors of the present application have revealed that leakage of charge to adjacent pixels can be sufficiently reduced if the taper angle lies in the range at least 60 degrees and not more than 90 degrees. The thickness of the pixel separation layer is preferably at least 10 nm and not more than 150 nm. A similar effect can be achieved also in a configuration having only a pixel electrode lacking a pixel separation layer. In this case, however, it is preferable to set the film thickness of the pixel electrode to be half or less the thickness the organic layer, or to impart forward taper at the ends of the pixel electrode, at a taper angle smaller than 60 degrees, since short circuits of the organic light-emitting element can be reduced thereby.

[Organic Compound Layer] The organic compound layer of the organic light-emitting element may be formed out of a single layer or multiple layers. In a case where the organic compound layer has multiple layers, these may be referred to as a hole injection layer, a hole transport layer, an electron blocking layer, a light-emitting layer, a hole blocking layer, an electron transport layer or an electron injection layer, depending on the function of the layer. The organic compound layer is mainly made up of organic compounds, but may contain inorganic atoms and inorganic compounds. For instance the organic compound layer may have copper, lithium, magnesium, aluminum, iridium, platinum, molybdenum or zinc. The organic compound layer may be disposed between the first electrode and the second electrode, and may be disposed in contact with the first electrode and the second electrode.

[Protective Layer] In the organic light-emitting element of the present embodiment, a protective layer may be provided on the second electrode. For instance, intrusion of water or the like into the organic compound layer can be reduced, and the occurrence of display defects also reduced, by bonding a glass provided with a moisture absorbent onto the second electrode. As another embodiment, a passivation film of for instance silicon nitride may be provided on the cathode, to reduce intrusion of water or the like into the organic compound layer. For instance, formation of the cathode may be followed by conveyance to another chamber, without breaking vacuum, whereupon a protective layer may be formed through formation of a silicon nitride film having a thickness of 2 μm by CVD. The protective layer may be provided by atomic deposition (ALD), after film formation by CVD. The material of the film formed by ALD is not limited, but may be for instance silicon nitride, silicon oxide or aluminum oxide. Silicon nitride may be further formed, by CVD, on the film having been formed by ALD. The film formed by ALD may be thinner than the film formed by CVD. Specifically, the thickness of the film formed by ALD may be 50% or less, or 10% or less.

[Color Filter] A color filter may be provided on the protective layer of the organic light-emitting element of the present embodiment. For instance a color filter having factored therein the size of the organic light-emitting element may be provided on another substrate, followed by affixing to a substrate having the organic light-emitting element provided thereon; alternatively, a color filter may be patterned by photolithography on the protective layer illustrated above. The color filter may be made up of a polymer.

[Planarization Layer] The organic light-emitting element of the present embodiment may have a planarization layer between the color filter and the protective layer. The planarization layer is provided for the purpose of reducing underlying layer unevenness. The planarization layer may be referred to as a resin layer in a case where the purpose of the planarization layer is not limited. The planarization layer may be made up of an organic compound, which may be a low-molecular or high-molecular compound, preferably a high-molecular compound.

The planarization layer may be provided above and below the color filter, and the constituent materials of the respective planarization layers may be identical or dissimilar. Concrete examples include polyvinylcarbazole resins, polycarbonate resins, polyester resins, ABS resins, acrylic resins, polyimide resins, phenolic resins, epoxy resins, silicone resins and urea resins.

[Microlens] The organic light-emitting element may have an optical member such as a microlens, on the light exit side. The microlens may be made up of for instance an acrylic resin or an epoxy resin. The purpose of the microlens may be to increase the amount of light extracted from the organic light-emitting element, and to control the direction of the extracted light. The microlens may have a hemispherical shape. In a case where the microlens has a hemispherical shape, then from among tangent lines that are in contact with the hemisphere there is a tangent line that is parallel to the insulating layer, such that the point of contact between that tangent line and the hemisphere is the apex of the microlens. The apex of the microlens can be established similarly in any cross section. That is, among tangent lines that are in contact with a semicircle of the microlens in a sectional view, there is a tangent line that is parallel to the insulating layer, such that the point of contact between that tangent line and the semicircle is the apex of the microlens.

A midpoint of the microlens can also be defined. Given a hypothetical line segment from the end point of an arc shape to the end point of another arc shape, in a cross section of the microlens, the midpoint of that line segment can be referred to as the midpoint of the microlens. The cross section for discriminating the apex and the midpoint may be a cross section that is perpendicular to the insulating layer.

The microlens has a first surface with a bulge and a second surface on the reverse side from that of the first surface. Preferably, the second surface is disposed closer to a functional layer than the first surface. In adopting such a configuration, the microlens must be formed the organic light-emitting element. In a case where the functional layer is an organic layer, it is preferable to avoid high-temperature processes in the manufacturing process. If a configuration is adopted in which the second surface is disposed closer to the functional layer than the first surface, the glass transition temperatures of all the organic compounds that make up the organic layer are preferably 100° C. or higher, and more preferably 130° C. or higher.

[Counter Substrate] The organic light-emitting element of the present embodiment may have a counter substrate on the planarization layer. The counter substrate is so called because it is provided at a position corresponding to the above-described substrate. The constituent material of the counter substrate may be the same as that of the substrate described above. The counter substrate can be used as the second substrate in a case where the substrate described above is used as the first substrate.

[Organic Layer] Each organic compound layer (hole injection layer, hole transport layer, electron blocking layer, light-emitting layer, hole blocking layer, electron transport layer, electron injection layer and so forth) that makes up the organic light-emitting element of the present embodiment is formed in accordance with one of the methods illustrated below.

A dry process such as vacuum deposition, ionization deposition, sputtering, plasma or the like can be used for the organic compound layers that make up the organic light-emitting element of the present embodiment. A wet process in which a layer is formed through dissolution in an appropriate solvent, relying on a known coating method (for instance spin coating, dipping, casting, LB film deposition to inkjet.) can resorted to instead of a dry process.

When a layer is formed for instance by vacuum deposition or by solution coating, crystallization or the like is unlikelier occur; this translates into superior stability over time. In a case where a film is formed in accordance with a coating method, the film can be formed by being combined with an appropriate binder resin.

Examples of binder resins include, although not limited to, polyvinylcarbazole resins, polycarbonate resins, polyester resins, ABS resins, acrylic resins, polyimide resins, phenolic resins, epoxy resins, silicone resins and urea resins. These binder resins may be used singly as one type, in the form of homopolymers or copolymers; alternatively, two or more types of binder resin may be used in the form of mixtures. Additives such as known plasticizers, antioxidants and ultraviolet absorbers may be further used concomitantly, as needed.

[Pixel Circuit] A light-emitting device having the organic light-emitting element of the present embodiment may have pixel circuits connected to respective organic light-emitting elements. The pixel circuits may be of active matrix type, and may control independently emission of light by the first organic light-emitting element and the second organic light-emitting element. Active matrix circuits may be voltage-programmed or current-programmed. A drive circuit has a pixel circuit for each pixel. Each pixel circuit may have an organic light-emitting element, a transistor that controls the emission luminance of the organic light-emitting element, a transistor that controls emission timing, a capacitor which holds the gate voltage of the transistor that controls emission luminance, and a transistor for connection to GND bypassing the light-emitting element.

The light-emitting device has a display area and a peripheral area disposed around the display area. The display area has pixel circuits, and the peripheral area has a display control circuit. The mobility of the transistors that make up the pixel circuits may be lower than the mobility of the transistors that make up the display control circuit. The slope of the current-voltage characteristic of the transistors that make up the pixel circuits may be gentler than the slope of the current-voltage characteristic of the transistors that make up the display control circuit. The slope of the current-voltage characteristics can be measured on the basis of a so-called Vg-Ig characteristic. The transistors that make up the pixel circuits are connected to light-emitting elements such as the first organic light-emitting element.

[Pixels] The organic light-emitting element of the present embodiment has a plurality of pixels. The pixels have sub-pixels that emit mutually different colors. The sub-pixels may have for instance respective RGB emission colors. The pixels emit light in a pixel opening region. This region is the same as the first region. The aperture diameter of the pixel openings may be 15 μm or smaller, and may be 5 μm or larger. More specifically, the aperture diameter of the pixel openings may be for instance 11 μm, or 9.5 μm, or 7.4 μm, or 6.4 μm. The spacing between sub-pixels may be 10 μm or smaller, specifically 8 μm, or 7.4 μm, or 6.4 μm.

The pixels can have any known arrangement in a plan view. For instance, the pixel layout may be a stripe arrangement, a delta arrangement, a penile arrangement or a Bayer arrangement. The shape of the sub-pixels in a plan view may be any known shape. For instance, the sub-pixel shape may be for instance quadrangular, such as rectangular or rhomboidal, or may be hexagonal. Needless to say, the shape of the sub-pixels is not an exact shape, and a shape close to that a of rectangle falls under a rectangular shape. Sub-pixel shapes and pixel arrays can be combined with each other.

[Use of the Organic Light-Emitting Element] The organic light-emitting element according to the present embodiment can be used as a constituent member of a display device or of a lighting device. Other uses of the organic light-emitting element include exposure light sources for electrophotographic image forming apparatuses, backlights for liquid crystal display devices, and light-emitting devices having color filters, in white light sources.

The display device may be an image information processing device having an image input unit for input of image information, for instance from an area CCD, a linear CCD or a memory card, and an information processing unit for processing inputted information, such that an inputted image is displayed on a display unit.

A display unit of an imaging device or of an inkjet printer may have a touch panel function. The driving scheme of this touch panel function may be an infrared scheme, a capacitive scheme, a resistive film scheme or an electromagnetic induction scheme, and is not particularly limited. The display device may also be used in a display unit of a multi-function printer.

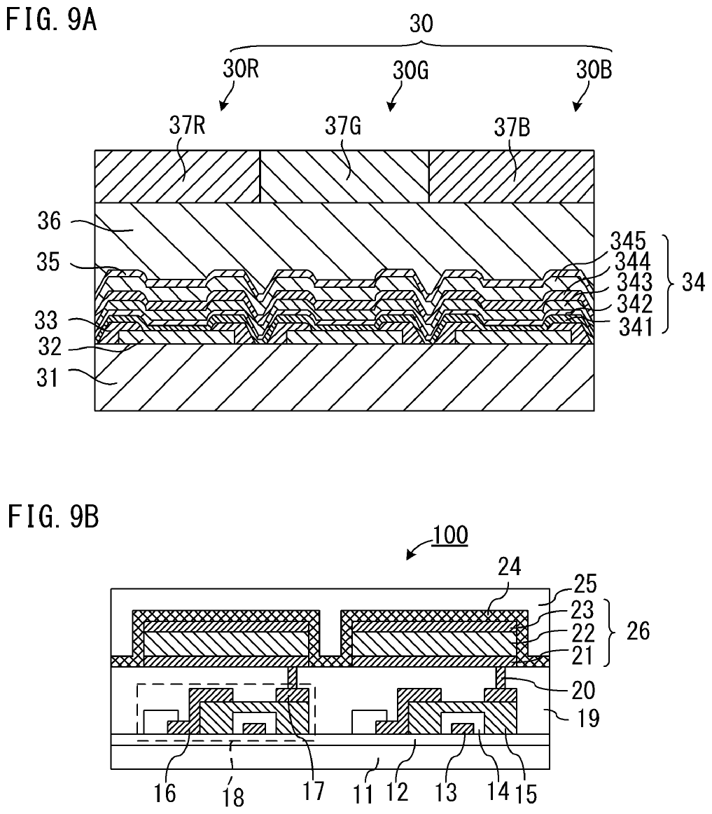

A display device provided with the organic light-emitting element according to the present embodiment will be explained next with reference to accompanying drawings. FIG. 9A and FIG. 9B are cross-sectional schematic diagrams illustrating examples of a display device having organic light-emitting elements and transistors connected to respective organic light-emitting elements. The transistors are an example of active elements. The transistors may be thin-film transistors (TFTs).

FIG. 9A is an example of a pixel, which is a constituent element of a display device having the organic light-emitting element according to the present embodiment. The pixel has sub-pixels 30. The sub-pixels are divided into 30R, 30G and 30B, depending on the respective emission light of the sub-pixel. The emission color may be made different on the basis of the wavelength emitted from the light-emitting layer; alternatively, the light emitted from each sub-pixel may be selectively transmitted or color-converted for instance by a respective color filter. Each sub-pixel has a reflective electrode 32 as a first electrode on an interlayer insulating layer 31, and an insulating layer 33 that covers the edge of the reflective electrode 32. Each sub-pixel has an organic compound layer 34 that covers the reflective electrode 32 and the insulating layer 33, a transparent electrode 35 as a second electrode, a protective layer 36, and a respective color filter 37R, 37G or 37B.

The interlayer insulating layer 31 may have transistors and capacitive elements disposed thereunder or in the interior. The transistors and the first electrode may be electrically connected for instance by way of contact holes (not shown).

The insulating layer 33 is also referred to as a bank or as pixel separation film. The insulating layer 33 is disposed covering the edge of the first electrode while surrounding the first electrode. Portions where the insulating layer is not disposed are in contact with the organic compound layer 34, yielding emission regions. The organic compound layer 34 has a hole injection layer 341, a hole transport layer 342, a first light-emitting layer 343, a second light-emitting layer 344 and an electron transport layer 345.

The transparent electrode 35, as the second electrode, may be a transparent electrode, a reflective electrode, or a semi-transparent electrode. The protective layer 36 reduces permeation of moisture into the organic compound layer. The protective layer 36 is illustrated herein in the form of one layer, but may be multiple layers. Each protective layer 36 may have an inorganic compound layer or an organic compound layer. The color filters are divided into a color filter 37R, a color filter 37G and a color filter 37B, according to the color thereof. The color filters may be formed on a planarization film, not shown. A resin protective layer, not shown, may be provided on the color filters. The color filters may be formed on the protective layer 36. Alternatively, the color filters may be affixed after having been provided on a counter substrate such as a glass substrate.

FIG. 9B illustrates a display device 100 having the organic light-emitting element of the present embodiment. The display device 100 has organic light-emitting elements 26 and TFTs 18 as an example of a transistor. The display device 100 is provided with a substrate 11 made up of glass, silicon or the like, and an insulating layer 12 at the top of the substrate 11. Respective active elements such as TFTs 18 are disposed on the insulating layer, such that a gate electrode 13, a gate insulating film 14 and a semiconductor layer 15 of each active element are disposed therein. Each TFT 18 is also made up of the semiconductor layer 15, a drain electrode 16 and a source electrode 17. An insulating film 19 is provided on the TFTs 18. An anode 21 and a source electrode 17 that make up a respective organic light-emitting element 26 are connected through a contact hole 20 provided in the insulating film.

The method for electrically connecting the electrodes (anode and cathode) included in each organic light-emitting element 26 and the electrodes (source electrode and drain electrode) included in the respective TFT is not limited to the implementation illustrated in FIG. 9B. Specifically, it suffices that either one from among the anode and the cathode be electrically connected to either a TFT source electrode or a TFT drain electrode. The acronym TFT signifies thin-film transistor.

In the display device 100 of FIG. 9B, the organic compound layer is illustrated as one layer, but the organic compound layer 22 may be a plurality of layers. A first protective layer 24 and a second protective layer 25 for reducing deterioration of the organic light-emitting element are provided on the cathode 23.

Although transistors are used as switching elements in the display device 100 of FIG. 9B, other switching elements may be used instead. The transistors used in the display device 100 of FIG. 9B are not limited to transistors that utilize a single-crystal silicon wafer, and may be thin-film transistors having an active layer on an insulating surface of a substrate. Examples of active layers include single-crystal silicon, non-single-crystal silicon such an amorphous silicon or microcrystalline silicon, as well as non-single-crystal oxide semiconductors such as indium zinc oxide or indium gallium zinc oxide. Thin-film transistors are also referred to as TFT elements.

The transistors included in the display device 100 of FIG. 9B may be formed in a substrate such as a Si substrate. The wording “formed in a substrate” signifies that transistors are produced by processing the substrate itself, for instance a Si substrate. That is, the feature of having transistors in the substrate may signify that the substrate and the transistors are integrally formed with each other.

The emission luminance of the organic light-emitting element according to the present embodiment is controlled by a TFT, which is an example of a switching element; an image can be thus displayed according to respective values of emission luminance, by providing a plurality of organic light-emitting elements within a plane. The switching element according to the present embodiment is not limited to a TFT, and may be a transistor made up of low-temperature polysilicon, or an active matrix driver formed on a substrate such as a Si substrate. The wording “on the substrate” can also signify herein “in the substrate”. The size of the display unit governs the choice of whether the transistors are to be provided in the substrate, or whether TFTs are to be used; if for instance the size of the display unit is about 0.5 inches, it is preferable to provide the organic light-emitting elements on a Si substrate.

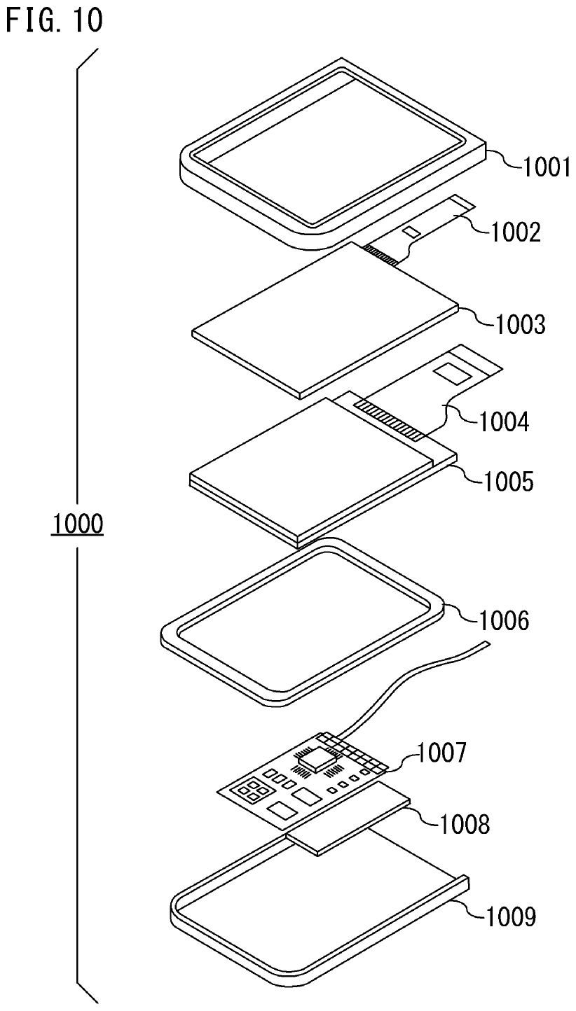

Next, FIG. 10 illustrates a schematic diagram depicting an example of a display device having an organic light-emitting element according to the present embodiment. A display device 1000 may have a touch panel 1003, a display panel 1005, a frame 1006, a circuit board 1007 and a battery 1008, between an upper cover 1001 and a lower cover 1009. The touch panel 1003 and the display panel 1005 are connected to flexible printed circuits FPCs 1002, 1004. Transistors are printed on the circuit board 1007. The battery 1008 may be omitted if the display device is not a portable device; even if the display device is a portable device, the battery 1008 may be provided at a different position.

The display device 1000 may have red, green and blue color filters. The color filters may be disposed in a delta arrangement of the above red, green and blue. The display device 1000 may be used as a display unit of a mobile terminal. In that case the display device 1000 may have both a display function and an operation function. Mobile terminals include mobile phones such as smartphones, tablets and head-mounted displays.

The display device 1000 may be used in a display unit of an imaging device that has an optical unit having a plurality of lenses, and that has an imaging element which receives light having passed through the optical unit. The imaging device may have a display unit that displays information acquired by the imaging element. The display unit may be a display unit exposed outside the imaging device, or may be a display unit disposed within a viewfinder. The imaging device may be a digital camera or a digital video camera.

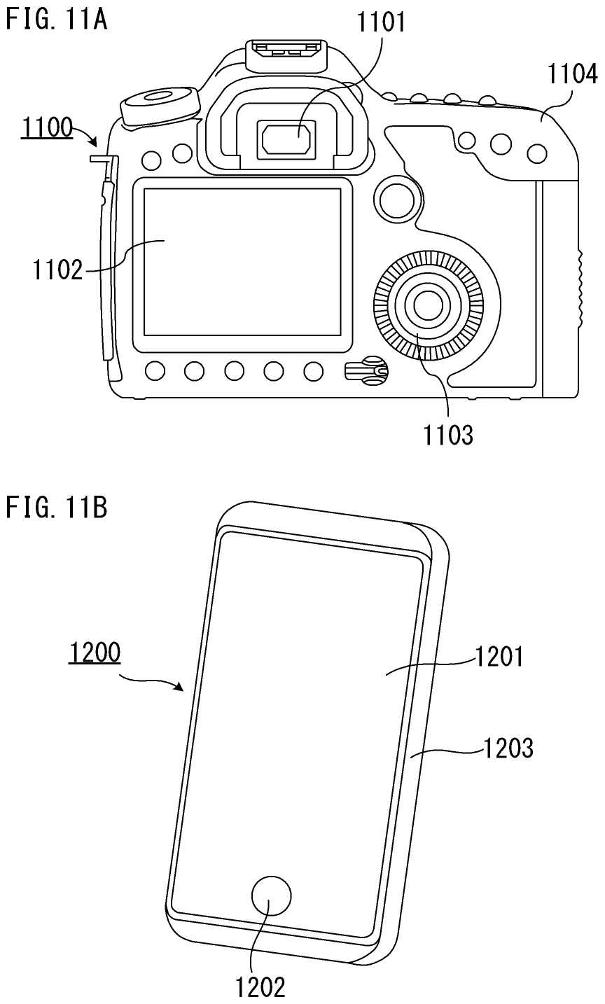

Next, FIG. 11A illustrates a schematic diagram depicting an example of an imaging device having the organic light-emitting element according to the present embodiment. An imaging device 1100 may have a viewfinder 1101, a rear display 1102, an operation unit 1103 and a housing 1104. The viewfinder 1101 may have the display device according to the present embodiment. In that case the display device may display not only an image to be captured, but also for instance environment information and imaging instructions. The environment information may include for instance external light intensity, external light orientation, the moving speed of a subject, and the chance of the subject being blocked by an obstacle.

The timing suitable for imaging is short, and hence information should be displayed as soon as possible. It is therefore preferable to configure the display device so as to have high response speed, using the organic light-emitting element of the present embodiment. A display device that utilizes the organic light-emitting element can be utilized more suitably than these devices or liquid crystal display devices, where high display speed is required.

The imaging device 1100 has an optical unit, not shown. The optical unit has a plurality of lenses, and forms an image on an imaging element accommodated in the housing 1104. The lenses can be focused through adjustment of the relative positions thereof. This operation can also be performed automatically. The imaging device may be referred to as a photoelectric conversion device. The photoelectric conversion device can encompass, as an imaging method other than sequential imaging, a method that involves detecting a difference relative to a previous image, and a method that involves cutting out part of a recorded image.

FIG. 11B is a schematic diagram illustrating an example of an electronic device having the organic light-emitting element according to the present embodiment. An electronic device 1200 includes a display unit 1201, an operation unit 1202, and a housing 1203. The housing 1203 may have a circuit, a printed board having the circuit, a battery, and a communication unit. The operation unit 1202 may be a button, or a touch panel-type reaction unit. The operation unit may be a biometric recognition unit which for instance performs unlocking upon recognition of a fingerprint. The electronic device having a communication unit can also be referred to as a communication device. The electronic device 1200 may further have a camera function, by being provided with a lens and an imaging element. Images captured by way of the camera function are displayed on the display unit. Examples of the electronic device include smartphones and notebook computers.

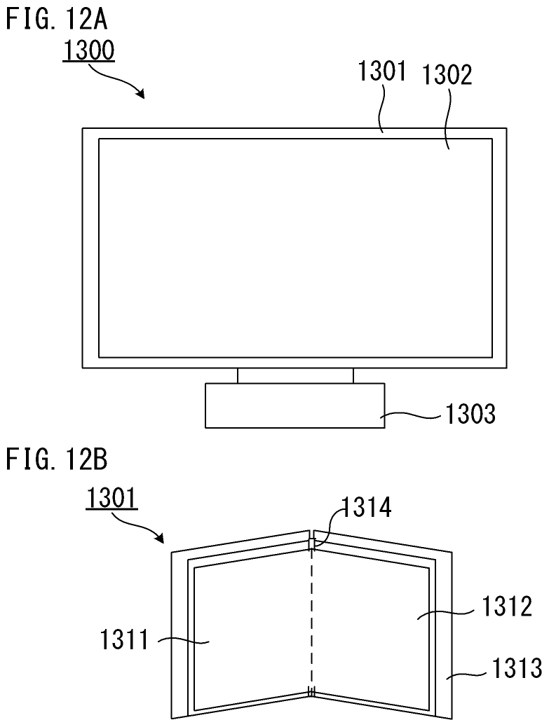

Next, FIG. 12A illustrates a schematic diagram depicting an example of a display device having the organic light-emitting element according to the present embodiment. FIG. 12A illustrates a display device 1300 such as a television monitor or PC monitor. The display device 1300 has a frame 1301 and a display unit 1302. The display unit 1302 may use the organic light-emitting element according to the present embodiment. The display device 1300 also has the frame 1301 and a base 1303 that supports the display unit 1302. The form of the base 1303 is not limited to the form in FIG. 12A. The lower side of the frame 1301 may also double as the base. The frame 1301 and the display unit 1302 may be curved. The radius of curvature of the foregoing may be at least 5000 mm and not more than 6000 mm.

FIG. 12B is a schematic diagram illustrating another example of a display device having the organic light-emitting element according to the present embodiment. A display device 1310 in FIG. 12B is a so-called foldable display device, configured to be foldable. The display device 1310 has a first display unit 1311, a second display unit 1312, a housing 1313 and a folding point 1314. The first display unit 1311 and the second display unit 1312 may have the organic light-emitting element according to the present embodiment. The first display unit 1311 and the second display unit 1312 may be one seamless display device. The first display unit 1311 and the second display unit 1312 can be separated at the folding point. The first display unit 1311 and the second display unit 1312 may display different images; alternatively, the first display unit and the second display unit may display one image.

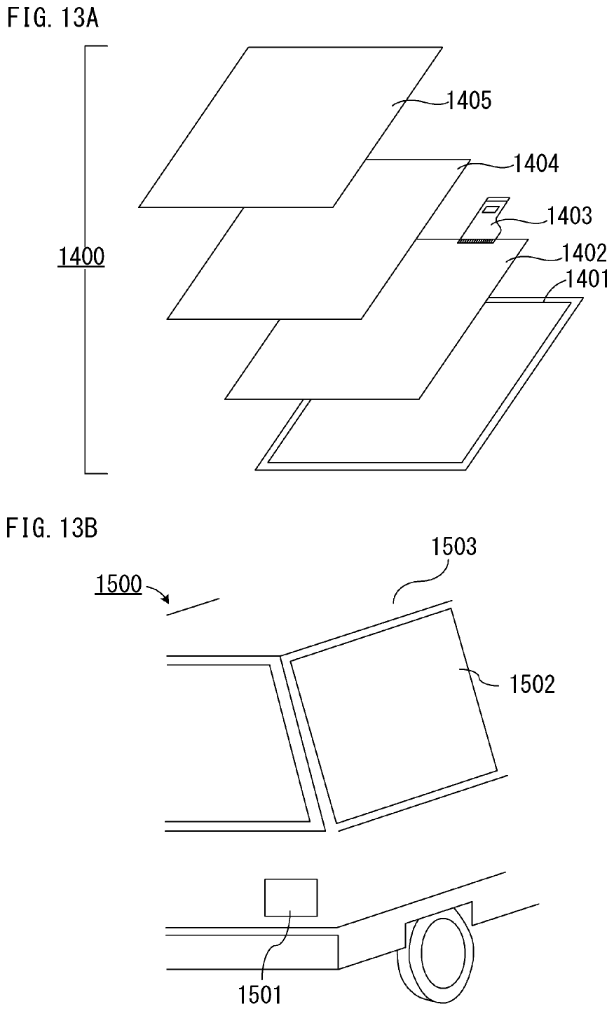

FIG. 13A illustrates next a schematic diagram depicting an example of a lighting device having the organic light-emitting element according to the present embodiment. A lighting device 1400 may have a housing 1401, a light source 1402, a circuit board 1403, an optical film 1404 and a light-diffusing part 1405. The light source has the organic light-emitting element according to the present embodiment. The optical film may be a filter that enhances the color rendering of the light source. The light-diffusing part allows effectively diffusing light from the light source, and allows delivering light over a wide area, for instance in exterior decorative lighting. The optical filter and the light-diffusing part may be provided on the light exit side of the lighting device. A cover may be provided on the outermost part, as the case may require.

The lighting device 1400 is for instance a device for indoor illumination. The lighting device may emit white, daylight white, or other colors from blue to red. The lighting device may have a light control circuit for controlling light having the foregoing emission colors. The lighting device 1400 may have the organic light-emitting element according to the present embodiment, and a power supply circuit connected thereto. The power supply circuit is a circuit that converts AC voltage to DC voltage. White denotes herein a color with a color temperature of 4200 K, and daylight white denotes a color with a color temperature of 5000 K. The lighting device 1400 may have a color filter. The lighting device 1400 may have a heat dissipation part. The heat dissipation part dumps, out of the device, heat from inside the device; the heat dissipation part may be made up of a metal or of liquid silicone rubber, exhibiting high specific heat.

FIG. 13B is a schematic diagram of an automobile, which is an example of a moving body having the organic light-emitting element according to the present embodiment. The automobile has tail lamps, being an example of a lamp. The automobile 1500 may have a tail lamp 1501, of a form such that the tail lamp is lit up when for instance a braking operation is performed.

The tail lamp 1501 has the organic light-emitting element according to the present embodiment. The tail lamp may have a protective member that protects the organic light-emitting element. The protective member may be made up of any material, so long as the material has a certain degree of high strength and is transparent; the protective member is preferably made up of polycarbonate or the like. For instance a furandicarboxylic acid derivative or an acrylonitrile derivative may be mixed with the polycarbonate.

The automobile 1500 may have a vehicle body 1503, and a window 1502 attached to the vehicle body 1503. The window may be a transparent display, unless the purpose of the window is to look ahead and behind the automobile. The transparent display may have the organic light-emitting element according to the present embodiment. In that case, constituent materials such as the electrodes of the organic light-emitting element are made up of transparent members.

The moving body having the organic light-emitting element according to the present embodiment may be for instance a vessel, an aircraft or a drone. The moving body may have a body frame and a lamp provided on the body frame. The lamp may emit light for indicating the position of the body frame. The lamp has the organic light-emitting element according to the present embodiment.

Also, the display device having the organic light-emitting element of the present embodiment can be used in a system that can be worn as a wearable device, such as smart glasses, HMDs or smart contacts. An imaging display device used in such an application example may have an imaging device capable of photoelectrically converting visible light, and a display device capable of emitting visible light.

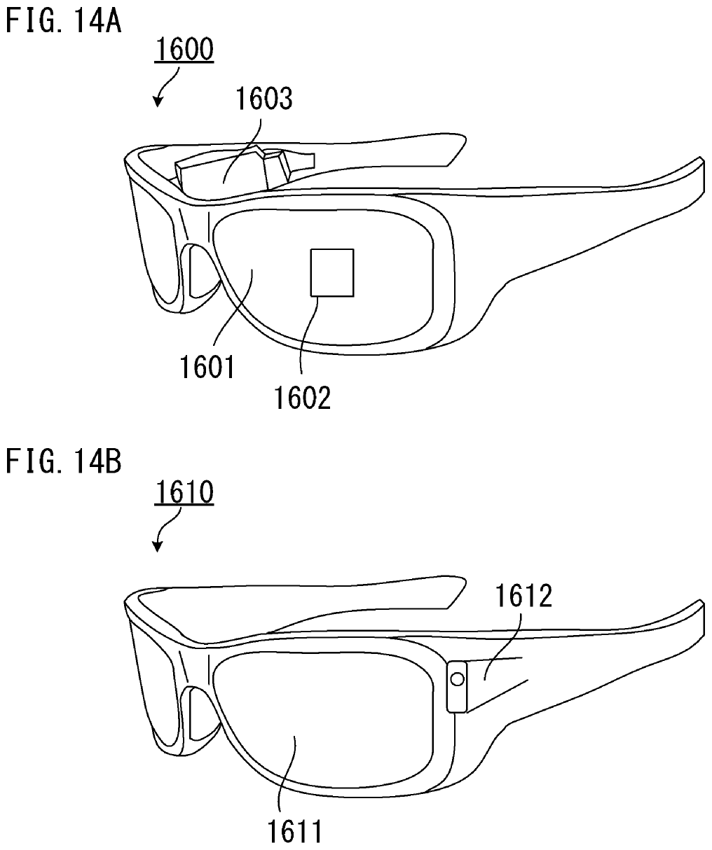

FIG. 14A illustrates spectacles 1600 (smart glasses) according to an application example of the display device having the organic light-emitting element of the present embodiment. An imaging device 1602 such as a CMOS sensor or a SPAD is provided on the front surface side of a lens 1601 of the spectacles 1600. A display device of the embodiments described above is provided on the back surface side of the lens 1601.

The spectacles 1600 further have a control device 1603. The control device 1603 functions as a power supply that supplies power to the imaging device 1602 and to the display device according to the embodiments. The control device 1603 controls the operations of the imaging device 1602 and of the display device. The lens 1601 has formed therein an optical system for condensing light onto the imaging device 1602.

FIG. 14B illustrates spectacles 1610 (smart glasses) according to another application example of the display device having the organic light-emitting element of the present embodiment. The spectacles 1610 have a control device 1612. The control device 1612 has mounted therein an imaging device corresponding to the imaging device 1602, and a display device. In a lens 1611 there is formed an optical system for projecting the light emitted by the display device in the control device 1612, such that an image is projected onto the lens 1611. The control device 1612 functions as a power supply that supplies power to the imaging device and to the display device, and controls the operations of the imaging device and of the display device. The control device may have a line-of-sight detection unit that detects the line of sight of the wearer. Infrared rays may be used herein for line-of-sight detection. An infrared light-emitting unit emits infrared light towards one eyeball of a user who is gazing at a display image. The infrared light emitted is reflected by the eyeball, and is detected by an imaging unit having a light-receiving element, whereby a captured image of the eyeball is obtained as a result. Impairment of the appearance of the image is reduced herein by having a reducing means for reducing light from the infrared light-emitting unit to the display unit, in a plan view.

The line of sight of the user with respect to the display image is detected on the basis of the captured image of the eyeball obtained through infrared light capture. Any known method can be adopted for line-of-sight detection using the captured image of the eyeball. As an example, a line-of-sight detection method can be resorted to that utilizes Purkinje images obtained through reflection of irradiation light on the cornea. More specifically, line-of-sight detection processing based on a pupillary-corneal reflection method is carried out herein. The line of sight of the user is detected by calculating a line-of-sight vector that represents the orientation (rotation angle) of the eyeball, on the basis of a Purkinje image and a pupil image included in the captured image of the eyeball, in accordance with a pupillary-corneal reflection method.

The display device having the organic light-emitting element according to the present embodiment may have an imaging device having a light-receiving element, and may control the display image of the display device on the basis of line-of-sight information about the user, from the imaging device.

Specifically, a first visual field area gazed at by the user and a second visual field area, other than the first visual field area, are determined in the display device on the basis of line-of-sight information. The first visual field area and the second visual field area may be determined by the control device of the display device; alternatively, the display device may receive visual field areas determined by an external control device. In a display area of the display device, the display resolution in the first visual field area may be controlled to be higher than the display resolution in the second visual field area. That is, the resolution in the second visual field area may set to be lower than that of the first visual field area.

The display area may have a first display area and a second display area different from the first display area, such that the display device selects the area of higher priority, from among the first display area and the second display area, on the basis of the line-of-sight information. The first display area and the second display area may be determined by the control device of the display device; alternatively, the display device may receive display areas determined by an external control device. The display device may control the resolution in a high-priority area so as to be higher than the resolution in areas other than high-priority areas. That is, the display device may lower the resolution in areas of relatively low priority.

Herein AI (Artificial Intelligence) may be used to determine the first visual field area and high-priority areas. The AI may be a model constructed to estimate, from an image of the eyeball, a line-of-sight angle, and the distance to an object lying ahead in the line of sight, using training data in the form of the image of the eyeball and the direction towards which the eyeball in the image was actually gazing at. An AI program may be provided in the display device, in the imaging device, or in an external device. In a case where an external device has the AI program, the AI program is transmitted to the display device via communication from the external device.

In a case where the display device performs display control on the basis of on visual recognition detection, the display device can be preferably used in smart glasses further having an imaging device that captures images of the exterior. The smart glasses can display captured external information in real time.

### EXAMPLES

Examples of the deposition mask 1 of the present embodiment will be explained next. The deposition mask 1 according to the present embodiment is not limited to the deposition mask illustrated in the following examples.

Table 1 sets out the results of repeating, 80 times, a process of bringing into close contact, and stripping off each other, the deposition mask 1 and the substrate, in the same way as at the time of vacuum deposition in the deposition apparatus.

TABLE 1

| | | PROTRUSION | | | | | | | |
|---|---|---|---|---|---|---|---|---|---|
| | | FRAME 8 | | | | | | | |
| | DEPOSITION | PLACE- | | CROSSPIECE 9 | | CROSSPIECE 10 | | MASK DAMAGE | |
| | MASK | MENT | | PRESENCE/ | | PRESENCE/ | | CONDITION | |
| | MATERIAL | AREA | METERIAL | ABSENCE | MATERIAL | ABSENCE | MATERIAL | DEFLECTION | DAMAGE |
| EXAMPLE1 | METAL | W | ◯ | — | — | | | 5.2% | NONE |
| EXAMPLE2 | METAL | W | ◯ | PRESENT | ◯ | PRESENT | □ | 1.5% | NONE |
| EXAMPLE3 | SILICON | W | □ | PRESENT | □ | PRESENT | ◯□ | 1.3% | NONE |
| EXAMPLE4 | SILICON | W | ◯ | — | — | PRESENT | ◯□ | 0.8% | NONE |
| EXAMPLE5 | METAL | W/2 | ◯ | PRESENT | ◯ | | | 1.0% | NONE |
| EXAMPLE6 | METAL | W/2 | ◯ | — | — | PRESENT | □ | 0.7% | NONE |
| EXAMPLE7 | RESIN | W/2 | ◯ | — | — | | | 0.8% | NONE |
| EXAMPLE8 | RESIN | W/2 | ◯ | PRESENT | □ | | | 0.5% | NONE |
| EXAMPLE9 | SILICON | W/2 | □ | PRESENT | ◯ | PRESENT | □ | 0.5% | NONE |
| EXAMPLE10 | SILICON | W/2 | ◯□ | — | — | PRESENT | ◯□ | 0.9% | NONE |
| EXAMPLE11 | SILICON | W/2 | ◯□ | PRESENT | □ | PRESENT | □ | 1.2% | NONE |
| COMPARATIVE | METAL | — | — | — | — | | | 43.1% | YES |
| EXAMPLE 1 | | | | | | | | | |
| COMPARATIVE | RESIN | W | SAME | — | — | PRESENT | SAME | 26.4% | YES |
| EXAMPLE 2 | | | MEMBER | | | | MEMBER | | |
| | | | AS MASK | | | | AS MASK | | |
| COMPARATIVE | RESIN | W | SAME | PRESENT | SAME | PRESENT | SAME | 19.7% | YES |
| EXAMPLE 3 | | | MEMBER | | MEMBER | | MEMBER | | |
| | | | AS MASK | | AS MASK | | AS MASK | | |

In the table, “DEPOSITION MASK MATERIAL” denotes the material used in the surface, of the deposition mask 1, at which the protrusions 5 come into contact with the substrate. The reference symbol W in the “PLACEMENT AREA” column indicates that the protrusions 5 are formed within a range of width W in the region 4 of the frame 8. The reference symbol W/2 in the “PLACEMENT AREA” column indicates that the protrusions 5 is formed at least within a range of width W/2 from the boundary 3, in the region 4 of the frame 8. The circle reference symbol “○” (circle symbol) in the “MATERIAL” column indicates that the material of a single or of multiple protrusions formed on the deposition mask is a non-magnetic material. The square reference symbol “□” (square symbol) in the “MATERIAL” column indicates that the material of a single or of multiple protrusions formed on the deposition mask is a magnetic material. The circle-plus-square reference symbol “○□” (circle symbol and square symbol) in the “MATERIAL” column indicates that the multiple protrusions formed on the deposition mask are a mixture of protrusions formed of a non-magnetic material and protrusions formed of a magnetic material.

The hyphen reference symbol “-” in the “FRAME 8” column and in the “CROSSPIECE 9” column indicates that no protrusions are formed on the frame 8 or on the crosspieces 9. The diagonal lines in the “CROSSPIECE 10” column indicate that there is no crosspiece 10 having a thickness smaller than that of the crosspieces 9, in the deposition mask. The numerical values in the “DEFLECTION” column denote the proportion of pixel openings having experienced deflection, relative to the pixel opening of the deposition mask, upon repeated stripping of the substrate and the deposition mask off each other, over a same predetermined number of repetitions.

The results for Examples 1 to 11 of the deposition mask according to the present embodiment in the table reveal that the present embodiment allows suitably preventing damage and deflection to a greater degree than in conventional deposition masks, as illustrated in the comparative examples, even upon repeated stripping of the substrate and the deposition mask off each other, regardless of the material of the deposition mask.

By reducing interactions between the substrate and the deposition mask, the art described in in the present disclosure allows reducing damage and deflection of a deposition mask at the time of stripping of a substrate and a deposition mask off each other, after deposition of a pixel opening pattern on the substrate.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2022-166808, filed on Oct. 18, 2022, which is hereby incorporated by reference herein in its entirety.

What is claimed is:

1. A deposition mask,
wherein a plurality of pixel openings are disposed in a surface, of a deposition mask, which is to face a substrate on which a deposition pattern is deposited,
wherein protrusions including a material different from a material included in the deposition mask are formed in a region which is located from a pixel opening that is disposed at an outermost peripheral portion in the surface, from among the plurality of pixel openings, up to an edge of the deposition mask, and
wherein in the deposition mask, a crosspiece which is located between two pixel openings adjacent to each other, from among the plurality of pixel openings include the material.

2. The deposition mask according to claim 1, wherein with W as a width of the region from the pixel opening disposed in the outermost peripheral portion, the protrusions are formed within a range of W/2 from the pixel opening disposed in the outermost peripheral portion.

3. The deposition mask according to claim 1, wherein the protrusion is formed on the crosspiece.

4. The deposition mask according to claim 1,
wherein the deposition mask has a frame in contact with a support member of the deposition mask, and
wherein a thickness of the frame is greater than a thickness of a first crosspiece, in a thickness direction of the deposition mask.

5. The deposition mask according to claim 1,
wherein the deposition mask has a frame in contact with a support member of the deposition mask, and a second crosspiece located between two pixel openings adjacent to each other, from among the plurality of pixel openings, and
d1, d2 and d3, as values of thickness of the frame, the first crosspieces and the second crosspieces, in a thickness direction of the deposition mask, satisfy Expression (1) below.
d1≥d2≥d3 (1)

6. The deposition mask according to claim 5, wherein the protrusions provided on the second crosspiece, in the surface.

7. The deposition mask according to claim 6, wherein the protrusion is formed of a magnetic material.

8. The deposition mask according to claim 1, wherein the protrusion is formed of a magnetic material or a non-magnetic material.

9. The deposition mask according to claim 1, wherein the substrate includes at least one selected from the group consisting of quartz, glass, silicon, resin and metal.

10. A method for producing an organic light-emitting element, comprising:
forming an organic compound layer using the deposition mask according to claim 1.

11. A display device, comprising:
an organic light-emitting element having an organic compound layer formed using the deposition mask according to claim 1.

12. An imaging device, comprising:
an organic light-emitting element having an organic compound layer formed using the deposition mask according to claim 1.

13. An electronic device, comprising:
an organic light-emitting element having an organic compound layer formed using the deposition mask according to claim 1.

14. A lighting device, comprising:
an organic light-emitting element having an organic compound layer formed using the deposition mask according to claim 1.

15. A moving body, comprising:
an organic light-emitting element having an organic compound layer formed using the deposition mask according to claim 1.
